(19) United States
(12) Patent Application Publication
(10) Pub. No.: US 2008/0197375 A1
(43) Pub. Date: Aug. 21, 2008

(54) Lateral-type light-emitting diode and method of manufacture thereof

(76) Inventor: Wen-Kung Sung, Taipei City (TW)

Correspondence Address: TROXELL LAW OFFICE PLLC, SUITE 1404, 5205 LEESBURG PIKE, FALLS CHURCH, VA, 22041, US

(21) Appl. No.: 11/706,429

(22) Filed: Feb. 15, 2007

(51) Int. Cl. H01L 33/00; H01L 21/00

(52) U.S. Cl. 257/99; 438/26; 257/E33.001

(57) ABSTRACT

A lateral-type light-emitting diode and a method of manufacture thereof are disclosed. The manufacture method comprises the steps of: (1) forming an outer shell on a substrate on which two metal electrodes are mounted; (2) forming chips and bonding wires on the inside of the outer shell; (3) injecting a transparent resin into the outer shell for forming a light-emitting diode package; and (4) finishing the manufacture process by cutting apart the center region of the light-emitting diode package between these two chips. The outer shell of the obtained lateral-type light-emitting diode is open on one side so the thickness of the lateral-type light-emitting diode can be reduced.

### FIELD OF THE INVENTION

The present invention relates to a lateral-type light-emitting diode and a method of manufacture thereof so as to simplify the manufacture process, reduce the thickness, and speed up the production of light-emitting diode.

### BACKGROUND OF THE INVENTION

The light-emitting diodes provide the advantages of low power consumption and long lifetime. As a result, the light-emitting diodes are widely applied to indicator lights of electronic products, backlights of mobile phones, traffic lights, advertisement boards, automobile brake lights, and so on. Recently, new light-emitting materials such as AlGaInP and AlGaInN are disclosed so as to further improve the brightness of the light-emitting diodes.

However, the conventional light-emitting diode emits the forward light. After coupling with the circuit board, the easiest way to change the lighting direction of the light-emitting diode is to change the mounting position of the circuit board. For example, if there is a need to allow the light-emitting diode to emit the lateral light, the circuit board is mounted vertically on the inside of the machine. If there is a need to allow the light-emitting diode to emit the downward light, the light-emitting diode is mounted on the top of the machine. Alternatively, the light-emitting diode is bended by an angle directly so as to transform the forward light into the lateral light. Moreover, as shown in FIG. 5, another lateral-type light-emitting diode is disclosed. This conventional light-emitting diode has an outer shell A having a certain thickness, wherein a chip B is mounted on the inside of the outer shell A. The outer shell A is made of industrial plastic material and is able to endure the high temperature. However, it is very hard to reduce the thickness of the outer shell A. Accordingly, there exists a need for reducing the thickness of the outer shell of the later-type light-emitting diode.

In view of the foregoing description, the motive of the present invention is to provide the general public with a lateral-type light-emitting diode and a method of manufacture thereof so as to simplify the manufacture process, reduce the thickness, and speed up the production of light-emitting diode.

### SUMMARY OF THE INVENTION

It is a primary object of the present invention to provide a lateral-type light-emitting diode and a method of manufacture thereof so as to simplify the manufacture process and speed up the production of light-emitting diode.

It is a secondary object of the present invention to provide a lateral-type light-emitting diode and a method of manufacture thereof so as to reduce the thickness.

In order to achieve the above-mentioned objects, a method of the present invention comprises the steps of: (1) forming an outer shell on a substrate on which two metal electrodes are mounted; (2) forming two chips and four bonding wires on the inside of the outer shell; (3) injecting a transparent resin into the outer shell for forming a light-emitting diode package; and (4) finishing the manufacture process by cutting apart the center region of the light-emitting diode package between these two chips.

The outer shell of the obtained lateral-type light-emitting diode is open on one side so the thickness of the lateral-type light-emitting diode can be reduced.

The aforementioned objects and advantages of the present invention will be readily clarified in the description of the preferred embodiments and the enclosed drawings of the present invention.

### BRIEF DESCRIPTION OF THE DRAWINGS

FIG. 1 is a process flow diagram of the present invention.

FIG. 2 is an elevational diagram of the present invention.

FIG. 3 is a schematic diagram showing the substrate of the present invention.

FIG. 4 is an elevational diagram showing the packaged structure of the present invention.

FIG. 5 is an elevational diagram showing the conventional structure.

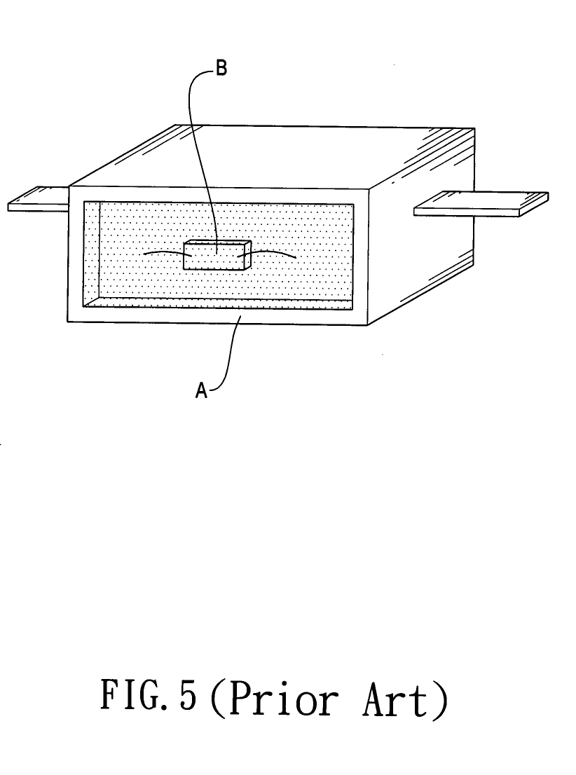

### DETAILED DESCRIPTION OF THE PREFERRED EMBODIMENT

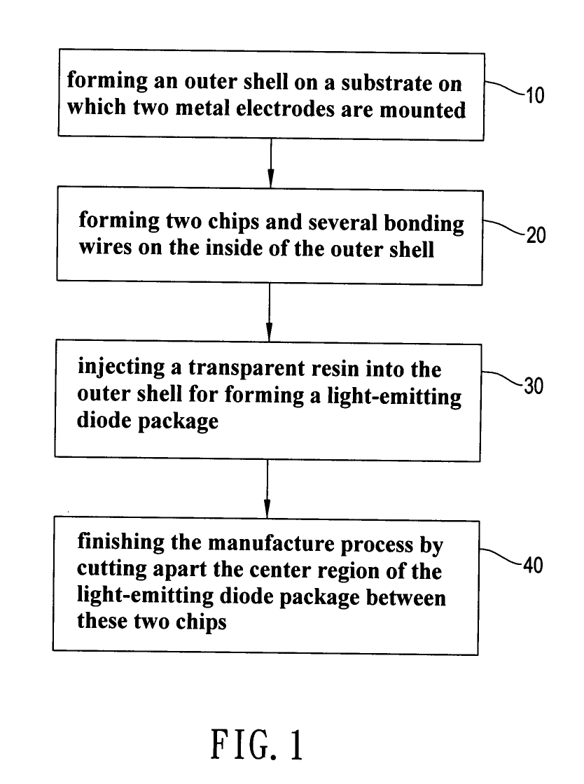

Referring to FIG. 1, the manufacture process of the present invention comprises the steps of;

(1) forming an outer shell on a substrate on which two metal electrodes are mounted 10;

(2) forming two chips and several bonding wires on the inside of the outer shell 20;

(3) injecting a transparent resin into the outer shell for forming a light-emitting diode package 30; and

(4) finishing the manufacture process by cutting apart the center region of the light-emitting diode package between these two chips 40.

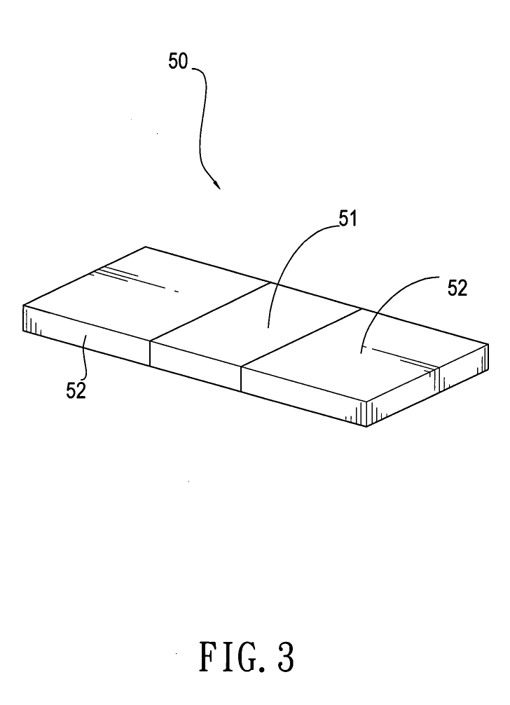

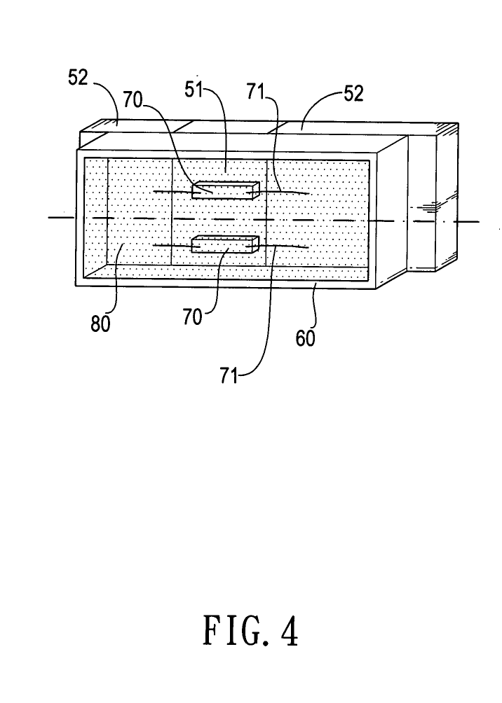

Referring simultaneously to FIG. 3 and FIG. 4, an insulating region 51 is formed the center portion of a substrate 50 so as to divide the substrate 50 into two conducting regions 52. The surface of the substrate 50 is covered with an outer shell 60. The outer shell 60 is located across these two conducting regions 52 and the insulating region 51. Two chips 70 are coupled with the insulting region 51. Each of the chips 70 is connected to the conducting regions 52 via two bonding wires 71, respectively. Thereafter, a transparent resin 80 is injected into the outer shell 60 so as to complete the light-emitting diode package on which these two chips 70 are mounted.

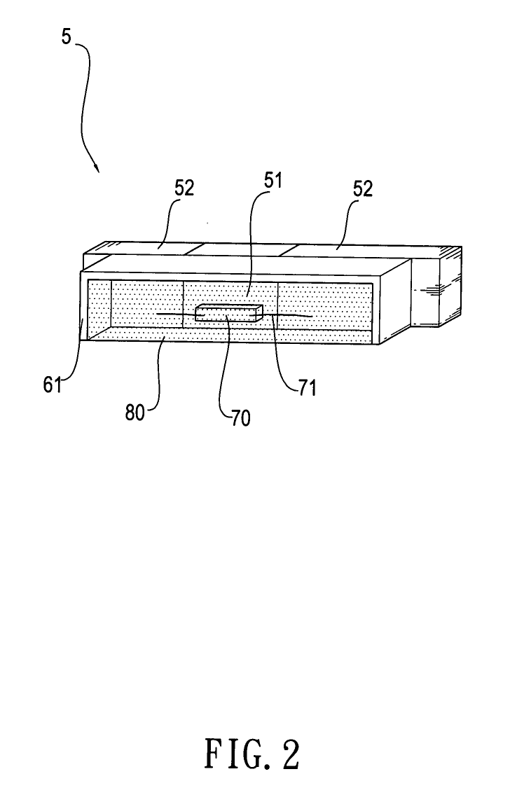

The light-emitting diode package is cut transversely from one end to the other end so as to separate these two chips 70 directly. As a result, after transverse cutting, two extremely tinned lateral-type light-emitting diodes 5 are formed, as shown in FIG. 2. Each of the lateral-type light-emitting diodes 5 has an inverse-U shaped outer shell 61, which is open on one side, so as to effectively reduce the thickness of the outer shell 60. In addition, each of the chips 70 is coupled with the insulating region 51 of the substrate 50. The chip 70 is electrically connected to these two conducting regions 52 via these two bonding wires 71, and the chip 70 and the bonding wires 71 are covered with the transparent resin 80.

In accordance with the foregoing description, the present invention has the following practical advantages:

1. The thickness of the lateral-type light-emitting diode of the present invention can be reduced significantly by the simplified manufacture process.

2. Two integral lateral-type light-emitting diodes can be obtained by the cutting step of the simplified manufacture process.

In summary, the present invention indeed achieves the expected objects by disclosing a lateral-type light-emitting diode and a method of manufacture thereof so as to simplify the manufacture process and reduce the thickness for improving thickness problem of the conventional lateral-type light-emitting diode. Accordingly, the present invention, which satisfies the requirement for patentability, is submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A method of manufacturing lateral-type light-emitting diodes comprising the steps of:
forming an outer shell on a substrate on which two metal electrodes are mounted;
forming two chips and a plurality of bonding wires on the inside of said outer shell;
injecting a transparent resin into said outer shell for forming a light-emitting diode package; and
cutting apart a center region of said light-emitting diode package between said two chips.

2. A method of manufacturing lateral-type light-emitting diodes of claim 1, wherein said substrate has an insulating region formed on a center portion thereof for separating said two metal electrodes from each other.

3. A lateral-type light-emitting diode, comprising:
a substrate having two metal electrodes mounted thereon;
an inverse-U shaped outer shell coupled with a top surface of said substrate;
a chip coupled with said substrate inside said outer shell and electrically connected to said two metal electrodes via two bonding wires; and
a transparent resin for packaging said substrate, said chip and said two boding wires so as to reduce the thickness of said lateral-type light-emitting diode.

4. A lateral-type light-emitting diode of claim 3, wherein said substrate has an insulating region formed on a center portion thereof for separating said two metal electrodes from each other.
